(19) United States
(12) Patent Application Publication
(10) Pub. No.: US 2015/0185812 A1
(43) Pub. Date: Jul. 2, 2015

(54) MEMORY SYSTEM AND COMPUTING SYSTEM

(71) Applicant: Samsung Electronics Co., Ltd., Suwon-si (KR)

(72) Inventors: Seok-Hun Hyun, Seongnam-si (KR); Jeong-Kyoum Kim, Seoul (KR); In-Dal Song, Seoul (KR); In-Sung Joe, Seoul (KR); Jung-Hwan Choi, Hwaseong-si (KR); Hyun-II Byun, Seongnam-si (KR); Yong-Won Jung, Seoul (KR)

(21) Appl. No.: 14/560,272

(22) Filed: Dec. 4, 2014

(30) Foreign Application Priority Data
Dec. 30, 2013 (KR) 10-2013-0166622

(51) Int. Cl. G06F 1/32; G11C 11/4074; G11C 7/10

(52) U.S. Cl. CPC G06F 1/3275; G11C 7/1072; G11C 11/4074

(57) ABSTRACT

A memory system includes a memory controller and a memory device. The memory device includes a first converter and a first power controller. The memory device is connected to the memory controller through a channel including at least one optical signal line. The first converter converts between at least one optical signal of the at least one optical signal line and at least one internal electrical signal of the memory device. The first power controller controls power consumption of the first converter based on an operating state of the memory device.

### CROSS-REFERENCE TO RELATED APPLICATION

This U.S. Non-provisional application claims priority under 35 USC §119 to Korean Patent Application No. 10-2013-0166622, filed on Dec. 30, 2013, in the Korean Intellectual Property Office (KIPO), the disclosure of which is incorporated by reference in its entirety herein.

### BACKGROUND

1. Technical Field

Example embodiments relate generally to power consumption control, and, more particularly, to power consumption control of a memory system including a converter configured to convert between an optical signal and an electrical signal, and a computing system including a converter configured to convert between an optical signal and an electrical signal.

2. Discussion of the Related Art

A memory system included in a computing system uses a high-speed optical interface to reduce time to access large amounts of data. The optical interface may consume a large amount of power during a conversion between an optical signal and an electrical signal.

### SUMMARY

At least one example embodiment of the inventive concept provides a memory system using an optical interface with reduced power consumption.

At least one example embodiment of the inventive concept provides a computing system using an optical interface with reduced power consumption.

According to example embodiments, a memory system including a memory controller and a memory device is provided. The memory device is connected to the memory controller through a channel including at least one optical signal line. The memory device includes a first converter and a first power controller. The first converter converts between at least one optical signal of the at least one optical signal line and at least one internal electrical signal of the memory device. The first power controller controls a power consumption of the first converter based on an operating state of the memory device.

In an example embodiment, the first converter may include an optical-to-electrical converter and an electrical-to-optical converter. The first power controller may generate a first power control signal controlling power consumption of the optical-to-electrical converter included in the first converter, and a second power control signal controlling a power consumption of the electrical-to-optical converter included in the first converter.

In an example embodiment, the first power controller may generate the first and the second power control signals based on a command signal and/or a control signal received from the memory controller.

In an example embodiment, the first power controller may generate the first and the second power control signals disabling the optical-to-electrical converter and the electrical-to-optical converter included in the first converter when the memory device executes an operation, which does not use the first converter, in response to the command signal and/or the control signal.

In an example embodiment, the first power controller may generate the first power control signal disabling the optical-to-electrical converter included in the first converter when the memory device executes an operation, which does not use the optical-to-electrical converter, in response to the command signal and/or the control signal. The first power controller may generate the second power control signal disabling the electrical-to-optical converter included in the first converter when the memory device executes an operation, which does not use the electrical-to-optical converter, in response to the command signal and/or the control signal.

In an example embodiment, a data signal, a data strobe signal, a command signal, a control signal, and a clock signal of the memory controller may be transferred to the memory device through the at least one optical signal line and the optical-to-electrical converter.

In an example embodiment, the channel may further include an electrical signal line connecting the memory controller and the memory device. A data signal of the memory controller may be transferred to the memory device through the at least one optical signal line and the optical-to-electrical converter. Each of a data strobe signal, a command signal, a control signal, and a clock signal of the memory controller may be transferred to the memory device through the at least one optical signal line and the optical-to-electrical converter, or through the electrical signal line.

In an example embodiment, the memory controller may further include a second converter configured to convert between at least one internal electrical signal of the memory controller and the at least one optical signal.

In an example embodiment, the memory controller may further include a second power controller. The second converter may include an optical-to-electrical converter and an electrical-to-optical converter. The second power controller may generate a third power control signal controlling a power consumption of the optical-to-electrical converter included in the second converter, and a fourth power control signal controlling power consumption of the electrical-to-optical converter included in the second converter

In an example embodiment, the first power controller may generate the first power control signal controlling a sensitivity of the optical-to-electrical converter included in the first converter based on a test signal transferred from the memory controller to the memory device, or the second power controller may generate the fourth power control signal controlling an output intensity of the electrical-to-optical converter included in the second converter based on a first flag signal generated by the first power controller based on the test signal.

In an example embodiment, the second power controller may generate the third power control signal controlling a sensitivity of the optical-to-electrical converter included in the second converter based on a test signal transferred from the memory device to the memory controller, or the first power controller may generate the second power control signal controlling an output intensity of the electrical-to-optical converter included in the first converter based on a second flag signal generated by the second power controller based on the test signal.

In an example embodiment, the first power controller may generate the first and the second power control signals based on a temperature of the first converter and/or a temperature of the memory device.

In an example embodiment, the at least one optical signal line may include a both-way optical signal line. A wavelength of a first optical signal transferred from the both-way optical signal line to the optical-to-electrical converter included in the first converter and a wavelength of a second optical signal transferred from the electrical-to-optical converter included in the first converter to the both-way optical signal line may be different.

In an example embodiment, the at least one optical signal line may include a one-way optical signal line. Optical signals, which have different wavelengths, may be transferred through the one-way optical signal line simultaneously.

In an example embodiment, the second converter may convert a data signal and a data strobe signal of the memory controller to the at least one optical signal. The memory controller may transfer the at least one optical signal to the memory device through the at least one optical signal line. The memory controller may transfer a control signal, a command signal, and a clock signal to the memory device through first electrical signal lines included in the channel. The memory controller may reconfigure a delay time of the data strobe signal based on a feedback signal received through second electrical signal lines included in the channel when the command signal is a write-leveling command signal. The first converter may convert a portion of the at least one optical signal to a converted data strobe signal of the memory device. The memory device may output the feedback signal, which represents a phase difference between the clock signal and the converted data strobe signal input to a plurality of DRAM chips, through the second electrical signal lines when the command signal is the write-leveling command signal.

In an example embodiment, the second converter may convert a data signal of the memory controller to the at least one optical signal. The memory controller may transfer the at least one optical signal to the memory device through the at least one optical signal line. The memory controller may transfer a data strobe signal, a control signal, a command signal, and a clock signal to the memory device through first electrical signal lines included in the channel. The memory controller may reconfigure a delay time of the data strobe signal and a delay time of the data signal based on a first feedback signal and a second feedback signal received through second electrical signal lines included in the channel when the command signal is a write-leveling command signal. The first converter may convert the at least one optical signal to a converted data signal of the memory device. The memory device may output the first feedback signal, which represents a phase difference between the clock signal and the data strobe signal input to a plurality of DRAM chips, and the second feedback signal, which represents a phase difference between the data strobe signal and the converted data signal input to the DRAM chips, when the command signal is the write-leveling command signal.

According to example embodiments, a computing system including a master circuit and a slave circuit is provided. The slave circuit is connected to the master circuit through a channel including at least one optical signal line. The slave circuit includes a converter and a power controller. The converter converts between at least one optical signal of the at least one optical signal line and at least one internal electrical signal of the slave circuit. The power controller controls a power consumption of the converter based on an operating state of the slave circuit.

As described above, a memory system according to example embodiments may reduce power consumption of the memory system based on an operating state of a memory device included in the memory system. A computing system according to example embodiments may reduce power consumption of the computing system based on an operating state of a slave circuit included in the computing system.

### BRIEF DESCRIPTION OF THE DRAWINGS

Example embodiments of the inventive concept will be more clearly understood from the following detailed description taken in conjunction with the accompanying drawings.

FIGS. 1 through 9 are block diagrams illustrating memory systems according to example embodiments.

FIGS. 10 and 11 are graphs illustrating example embodiments of controlling power consumption of converters included in the memory system of FIG. 3.

FIG. 12 is a block diagram illustrating a memory system according to an example embodiment.

FIG. 13 is a timing diagram illustrating a write-leveling operation of the memory system of FIG. 12.

FIG. 14 is a block diagram illustrating a memory system according to an example embodiment.

FIG. 15 is a block diagram illustrating a computing system according to an example embodiment.

FIGS. 16 and 17 are flow charts illustrating example embodiments of a write-leveling method of a memory system according to example embodiments.

FIG. 18 is a block diagram illustrating a mobile system including a memory system according to example embodiments.

FIG. 19 is a block diagram illustrating a computing system including a memory system according to example embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

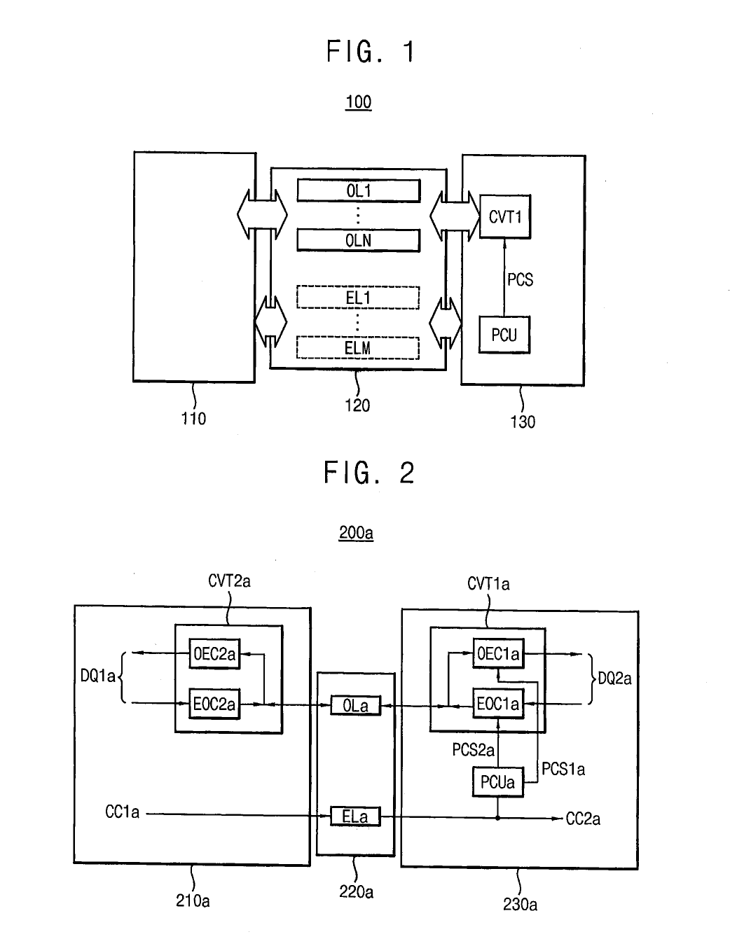

FIGS. 1 through 9 are block diagrams illustrating memory systems according to example embodiments.

Referring to FIG. 1, a memory system 100 includes a memory controller 110, a memory device 130, and a channel 120. The memory device 130 includes a first converter CVT1 and a first power controller PCU. The memory device 130 is connected to the memory controller 110 through the channel 120 including at least one optical signal line OL1, OLN. In an example embodiment, the channel 120 may further include at least one electrical signal line EL1, ELM. The first converter CVT1 converts between at least one optical signal of the optical signal line OL1, OLN and at least one internal electrical signal of the memory device 130. The first power controller PCU controls a power consumption of the first converter CVT1 based on an operating state of the memory device 130.

In an example embodiment, the operating state of the memory device 130 may be determined based on the command signal and/or the control signal transferred from the memory device 130. In another example embodiment, the operating state of the memory device 130 may be determined based on a first test signal, which is transferred from the memory controller 110 to the memory device 130, or a second test signal, which is transferred from the memory device 130 to the memory controller 110. In still another example embodiment, the operating state of the memory device 130 may be determined based on a temperature of the first converter CVT1 or a temperature of the memory device 130.

The command signal indicates a signal, which is generated in the memory controller 110 and to control functional operation of the memory device 130. The command signal may be a read command signal or a write command signal.

The control signal indicates a signal, which is used to control the performance (e.g. operation speed or power consumption) of the memory device 130 and/or the operation mode of the memory device 130.

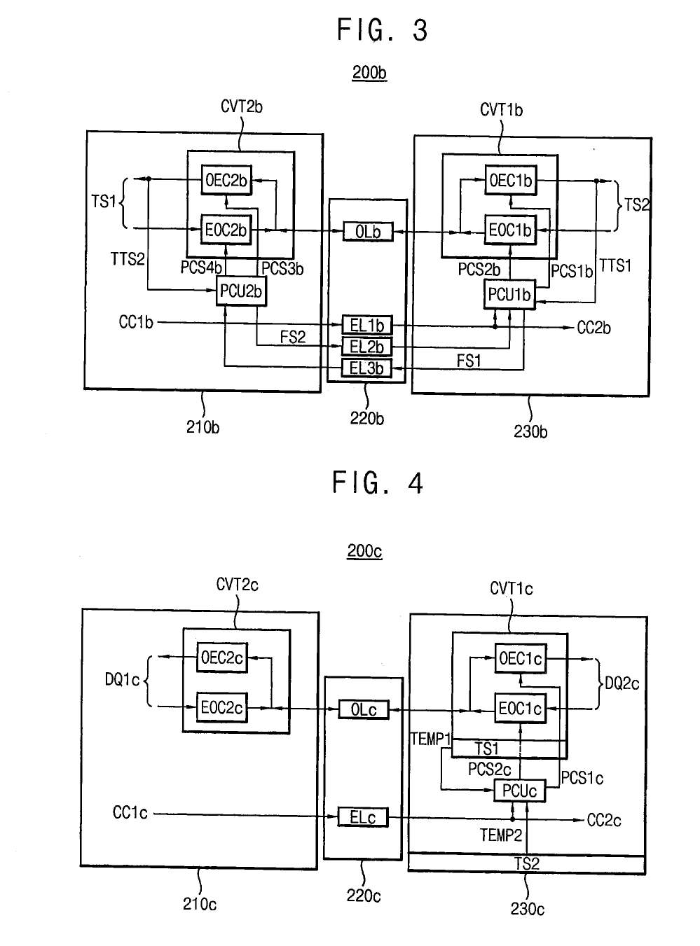

Example embodiments in which the first power controller PCU controls the power consumption of the first converter CVT1 based on the command signal and/or the control signal transferred to the memory device 130 will be described with the references to FIGS. 2 through 9. Example embodiments in which the first power controller PCU controls the power consumption of the first converter CVT1 based on the first test signal, which is transferred from the memory controller 110 to the memory device 130, and/or the second test signal, which is transferred from the memory device 130 to the memory controller 110, and a second power controller included in the memory controller 110 controls the power consumption of a second converter included in the memory controller 110 will be described with the reference to FIG. 3. Example embodiments in which the first power controller CPU controls the power consumption of the first converter CVT1 based on the temperature of the first converter CVT1 and/or the temperature of the memory device 130 will be described with the reference to FIG. 4.

Referring to FIG. 2, a memory system 200a includes a memory controller 210a, a memory device 230a, and a channel 220a. The memory controller 210a and the memory device 230a are connected through the channel 220a including an optical signal line OLa and an electrical signal line ELa. The memory device 230a may include a first converter CVT1a and a first power controller PCUa. The memory controller 210a may include a second converter CVT2a. The first converter CVT1a may include a first optical-to-electrical converter OEC1a and a first electrical-to-optical converter EOC1a. The second converter CVT2a may include a second optical-to-electrical converter OEC2a and a second electrical-to-optical converter EOC2a.

The optical signal line OLa may be a both-way optical signal line or a one-way optical signal line. FIG. 2 illustrates an embodiment in which the optical signal line OLa is a both-way optical signal line. A wavelength of an optical signal transferred from the memory controller 210a to the memory device 230a and a wavelength of an optical signal transferred from the memory device 230a to the memory controller 210a may be different.

The second electrical-to-optical converter EOC2a may convert a first data signal DQ1a of the memory controller 210a to a first optical signal. The first optical signal may be transferred to the first optical-to-electrical converter OEC1a through the optical signal line OLa. The first optical-to-electrical converter OEC1a may convert the first optical signal to a second data signal DQ2a. On the other hand, the first electrical-to-optical converter EOC1a may convert a second data signal DQ2a to a second optical signal. The second optical signal may be transferred to the second optical-to-electrical converter OEC2a through the optical signal line OLa. The second optical-to-electrical converter OEC2a may convert the second optical signal to the first data signal DQ1a. The command signal and the control signal CC1a of the memory controller 210a may be transferred to the memory device 230a through the electrical signal line ELa included in the channel 220a.

The first power controller PCUa may control a power consumption of the first converter CVT1a based on the operating state of the memory device 230a. The first power controller PCUa may generate a first power control signal PCS1a, which controls a power consumption of the first optical-to-electrical converter OEC1a, and a second power control signal PCS2a, which controls a power consumption of the first electrical-to-optical converter EOC1a, based on the command signal and the control signal CC2a transferred from the memory controller 210a.

The first power controller PCUa may generate the first and the second power control signals PCS1a, PCS2a disabling the first optical-to-electrical converter OEC1a and the first electrical-to-optical converter EOC1a included in the first converter CVT1a when the memory device 230a executes an operation, which does not use the first converter CVT1a, in response to the command signal or the control signal CC2a.

The first power controller PCUa may generate the first power control signal PCS1a disabling the first optical-to-electrical converter OEC1a included in the first converter CVT1a when the memory device 230a executes an operation, which does not use the first optical-to-electrical converter OEC1a, in response to the command signal and the control signal CC2a. The first power controller PCUa may generate the second power control signal PCS2a disabling the first electrical-to-optical converter EOC1a included in the first converter CVT1a when the memory device 230a executes an operation, which does not use the first electrical-to-optical converter EOC1a, in response to the command signal and the control signal CC2a.

The data signal DQ1a may be transferred to the memory device 230a through the optical signal line OLa and the first optical-to-electrical converter OEC1a.

Referring to FIG. 3, a memory system 200b includes a memory controller 210b, a memory device 230b, and a channel 220b. The memory controller 210b and the memory device 230b are connected through the channel 220b including an optical signal line OLb and electrical signal lines EL1b, EL2b, and EL3b. The memory device 230b may include a first converter CVT1b and a first power controller PCU1b. The memory controller 210b may include a second converter CVT2b and a second power controller PCU2b. The first converter CVT1b may include a first optical-to-electrical converter OEC1b and a first electrical-to-optical converter EOC1b. The second converter CVT2b may include a second optical-to-electrical converter OEC2b and a second electrical-to-optical converter EOC2b.

The first power controller PCU1b may generate a first power control signal PCS1b, which controls a power consumption of the first optical-to-electrical converter OEC1b, and a second power control signal PCS2b, which controls a power consumption of the first electrical-to-optical converter EOC1b. The first power controller PCU1b may generate the first and the second power control signal PCS1b, PCS2b based on the command signal and the control signal CC2b transferred from the memory controller 210b. The second power controller PCU2b may generate a third power control signal PCS3b, which controls a power consumption of the second optical-to-electrical converter OEC2b, and a fourth power control signal PCS4b, which controls a power consumption of the second electrical-to-optical converter EOC2b.

The second electrical-to-optical converter EOC2b may convert a first test signal TS1 of the memory controller 210b to a first optical signal. The first optical signal may be transferred to the first optical-to-electrical converter OEC1b through the optical signal line OLb. The first optical-to-electrical converter OEC1b may convert the first optical signal to a transferred first test signal TTS1. The first power controller PCU1b may generate the first power control signal PCS1b controlling a sensitivity of the first optical-to-electrical converter OEC1b based on the transferred first test signal TTS1. The second power controller PCU2b may generate the fourth power control signal PCS4b controlling an output intensity of the second electrical-to-optical converter EOC2b included in the second converter CVT2b based on a first flag signal FS 1 which is generated by the first power controller PCU1b based on the transferred first test signal TTS1.

When the first power controller PCU1b receives the transferred first test signal TTS1 having a lower intensity than a lower boundary intensity, the first power controller PCU1b may generate the first power control signal PCS1b that makes the first optical-to-electrical converter OEC1b more sensitive to an optical signal. When the first power controller PCU1b receives the transferred first test signal TTS1 having a lower intensity than the lower boundary intensity, the first power controller PCU1b may control the first flag signal FS1 so that the second power controller PCU2b generates the fourth power control signal PCS4b which enhances the output intensity of the second electrical-to-optical converter EOC2b. When the first power controller PCU1b receives the transferred first test signal TTS1 having a higher intensity than a upper boundary intensity, the first power controller PCU1b may generate the first power control signal PCS1b that makes the first optical-to-electrical converter OEC1b less sensitive to an optical signal. When the first power controller PCU1b receives the transferred first test signal TTS1 having a higher intensity than the upper boundary intensity, the first power controller PCU1b may control the first flag signal FS1 so that the second power controller PCU2b generates the fourth power control signal PCS4b which reduces the output intensity of the second electrical-to-optical converter EOC2b.

The first power controller PCU1b may determine the lower boundary intensity of the transferred first test signal TTS1 and the upper boundary intensity of the transferred first test signal TTS1 according to an extinction ratio.

The first electrical-to-optical converter EOC1b may convert a second test signal TS2 of the memory device 230b to a second optical signal. The second optical signal may be transferred to the second optical-to-electrical converter through the optical signal line OLb. The second optical-to-electrical converter OEC2b may convert the second optical signal to a transferred second test signal TTS2. The second power controller PCU2b may generate the third power control signal PCS3b controlling a sensitivity of the second optical-to-electrical converter OEC2b based on the transferred second test signal TTS2. The first power controller PCU1b may generate the second power control signal PCS2b controlling the output intensity of the first electrical-to-optical converter EOC1b based on a second flag signal FS2 which is generated by the second power controller PCU2b based on the transferred second test signal TTS2.

When the second power controller PCU2b receives the transferred second test signal TTS2 having a lower intensity than a lower boundary intensity, the second power controller PCU2b may generate the third power control signal PCS3b that makes the second optical-to-electrical converter OEC2b more sensitive to an optical signal. When the second power controller PCU2b receives the transferred second test signal TTS2 having a lower intensity than the lower boundary intensity, the second power controller PCU2b may control the second flag signal FS2 so that the first power controller PCU1b generates the second power control signal PCS2b which enhances the output intensity of the first electrical-to-optical converter EOC1b. When the second power controller PCU2b receives the transferred second test signal TTS2 having a higher intensity than a upper boundary intensity, the second power controller PCU2b may generate the third power control signal PCS3b that makes the second optical-to-electrical converter OEC2b less sensitive to an optical signal. When the second power controller PCU2b receives the transferred second test signal TTS2 having a higher intensity than the upper boundary intensity, the second power controller PCU2b may control the second flag signal FS2 so that the first power controller PCU1b generates the second power control signal PCS2b which reduces the output intensity of the first electrical-to-optical converter EOC1b.

The second power controller PCU2b may determine the lower boundary intensity of the transferred second test signal TTS2 and the upper boundary intensity of the transferred second test signal TTS2 according to an extinction ratio.

Controlling power consumption using the first and the second power controllers PCU1b, PCU2b may be performed during initialization process of the memory system 200b. Controlling power consumption using the first and the second power controllers PCU1b, PCU2b may be performed during refresh process if the memory device 230b includes DRAM. Controlling power consumption using the first and the second power controllers PCU1b, PCU2b may be performed when a temperature of the first converter CVT1b and/or a temperature of the memory device 230b exceeds a pre-determined temperature boundary. Controlling power consumption using the first and the second power controllers PCU1b, PCU2b may be performed periodically.

Referring to FIG. 4, a memory system 200c includes a memory controller 210c, a memory device 230c, and a channel 220c. The memory controller 210c and the memory device 230c are connected through the channel 220c including an optical signal line OLc and an electrical signal line ELc. The memory device 230c may include a first converter CVT1c, a first temperature sensor TS1 of the first converter CVT1c, a power controller PCUc, and a second temperature sensor TS2 of the memory device 230c. The memory controller 210c may include a second converter CVT2c. The first converter CVT1c may include a first optical-to-electrical converter OEC1c and a first electrical-to-optical converter EOC1c. The second converter CVT2c may include a second optical-to-electrical converter OEC2c and a second electrical-to-optical converter EOC2c.

A first data signal DQ1c may be transferred from the memory controller 210c to the memory device 230c through the second electrical-to-optical converter EOC2c, the optical signal line OLc, and the first optical-to-electrical converter OEC1c. A second data signal DQ2c may be transferred from the memory device 230c to the memory controller 210c through the first electrical-to-optical converter EOC1c, the optical signal line OLc, and the second optical-to-electrical converter OEC2c.

The power controller PCUc may generate a first power control signal PCS1c and a second power control signal PCS2c based on the first converter's temperature TEMP1 measured by the first temperature sensor TS 1 or the memory device's temperature TEMP2 measured by the second temperature sensor TS2.

In an example embodiment, when the first converter's temperature TEMP1 maintains a low value and the first converter CVT1c is not used, the power controller PCUc may stop delivering power to the first converter CVT1c. In another example embodiment, when the first converter's temperature TEMP1 maintains a low value and the first optical-to-electrical converter OEC1c is not used, the power controller PCUc may stop delivering power to the first optical-to-electrical converter OEC1c. In still another example embodiment, when the first converter's temperature TEMP1 maintains a low value and the first electrical-to-optical converter EOC1c is not used, the power controller PCUc may stop delivering power to the first electrical-to-optical converter EOC1c.

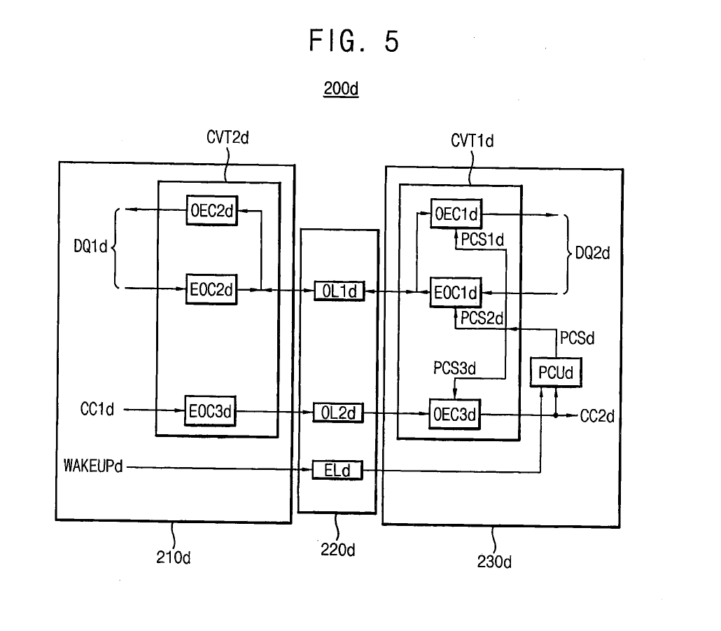

Referring to FIG. 5, a memory system 200d includes a memory controller 210d, a memory device 230d, and a channel 220d. The memory controller 210d and the memory device 230d are connected through the channel 220d including a first optical signal line OL1d, a second optical signal line OL2d, and an electrical signal line ELd. The memory device 230d may include a first converter CVT1d and a power controller PCUd. The memory controller 210d may include a second converter CVT2d. The first converter CVT1d may include a first optical-to-electrical converter OEC1d, a first electrical-to-optical converter EOC1d, and a third optical-to-electrical converter OEC3d. The second converter CVT2d may include a second optical-to-electrical converter OEC2d, a second electrical-to-optical converter EOC2d, and a third electrical-to-optical converter EOC3d.

A first data signal DQ1d may be transferred from the memory controller 210d to the memory device 230d through the second electrical-to-optical converter EOC2d, the first optical signal line OL1d, and the first optical-to-electrical converter OEC1d. A second data signal DQ2d may be transferred from the memory device 230d to the memory controller 210d through the first electrical-to-optical converter EOC1d, the first optical signal line OL1d, and the second optical-to-electrical converter OEC2d.

A command signal and a control signal CC1d of the memory controller 210d may be transferred to the memory device 230d as a command signal and a control signal CC2d through the third electrical-to-optical converter EOC3d, the second optical signal line OL2d, and the third optical-to-electrical converter OEC3d. Wake-up signal WAKEUPd may be transferred from the memory controller 210d to the memory device 230d through the electrical signal line ELd.

The power controller PCUd may generate a power control signal PCSd based on the command signal and the control signal CC2d of the memory device 230d. The power control signal PCSd may include a first power control signal PCS1d, a second power control signal PCS2d, and a third power control signal PCS3d. A power consumption of the first optical-to-electrical converter OEC1d may be controlled by changing a power delivering level of the first optical-to-electrical converter OEC1d based on the first power control signal PCS1d. A power consumption of the first electrical-to-optical converter EOC1d may be controlled by changing a power delivering level of the first electrical-to-optical converter EOC1d based on the second power control signal PCS2d. A power consumption of the third optical-to-electrical converter OEC3d may be controlled by changing a power delivering level of the third optical-to-electrical converter OEC3d based on the third power control signal PCS3d.

Because the command signal and control signal CC1d of the memory controller 210d cannot be transferred to the memory device 230d when the third optical-to-electrical converter OEC3d is disabled by stopping power delivery, the power controller PCUd may generate the power control signal PCSd, which enables the first converter CVT1d or the third optical-to-electrical converter OEC3d to deliver power thereto, based on the wake-up signal WAKEUPd.

The first optical signal line OL1d may be a both-way optical signal line. A wavelength of a first optical signal transferred from the first optical signal line OL1d to the first optical-to-electrical converter OEC1d and a wavelength of a second optical signal transferred from the first electrical-to-optical converter EOC1d to the first optical signal line OL1d may be different.

The second optical signal line OL2d may be a one-way optical signal line. Optical signals, which have different wavelengths, may be transferred through the second optical signal line OL2d.

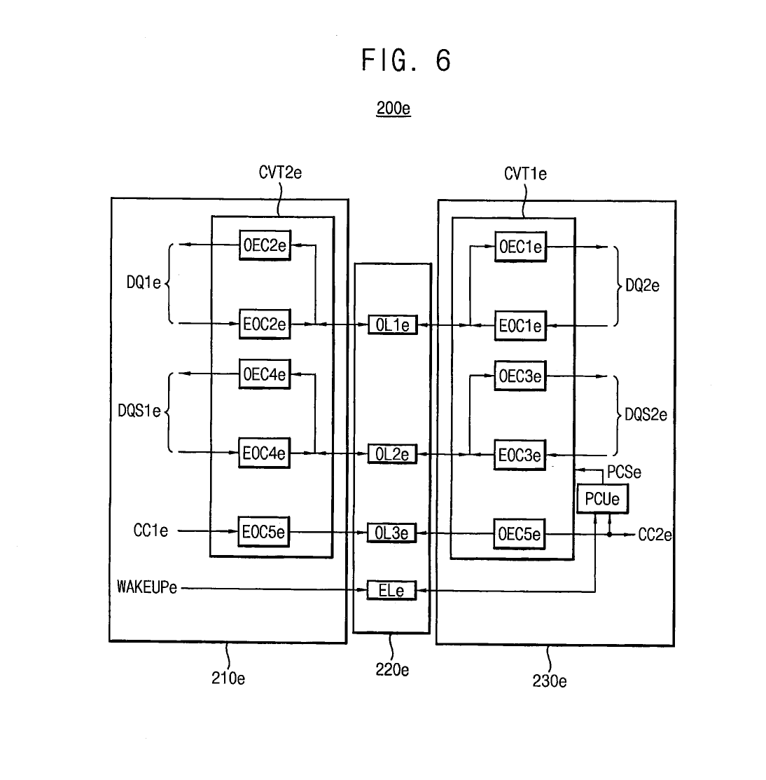

Referring to FIG. 6, a memory system 200e includes a memory controller 210e, a memory device 230e, and a channel 220e. The memory controller 210e and the memory device 230e are connected through the channel 220e including a first optical signal line OL1e, a second optical signal line OL2e, a third optical signal line OL3e, and an electrical signal line ELe. The memory device 230e may include a first converter CVT1e and a power controller PCUe. The memory controller 210e may include a second converter CVT2e. The first converter CVT1e may include a first optical-to-electrical converter OEC1e, a first electrical-to-optical converter EOC1e, a third optical-to-electrical converter OEC3e, a third electrical-to-optical converter EOC3e, and a fifth optical-to-electrical converter OEC5. The second converter CVT2e may include a second optical-to-electrical converter OEC2e, a second electrical-to-optical converter EOC2e, a fourth optical-to-electrical converter OEC4e, a fourth electrical-to-optical converter EOC4e, and a fifth electrical-to-electrical converter EOC5e.

A first data signal DQ1e may be transferred from the memory controller 210e to the memory device 230e through the second electrical-to-optical converter EOC2e, the first optical signal line OL1e, and the first optical-to-electrical converter OEC1e. A second data signal DQ2e may be transferred from the memory device 230e to the memory controller 210e through the first electrical-to-optical converter EOC1e, the first optical signal line OL1e, and the second optical-to-electrical converter OEC2e.

A first data strobe signal DQS1e may be transferred from the memory controller 210e to the memory device 230e through the fourth electrical-to-optical converter EOC4e, the second optical signal line OL2e, and the third optical-to-electrical converter OEC3e. A second data strobe signal DQS2e may be transferred from the memory device 230e to the memory controller 210e through the third electrical-to-optical converter EOC3e, the second optical signal line OL2e, and the fourth optical-to-electrical converter OEC4e.

A command signal and a control signal CC1e of the memory controller 210e may be transferred to the memory device 230e as a command signal and a control signal CC2e through the fifth electrical-to-optical converter EOC5e, the third optical signal line OL3e, and the fifth optical-to-electrical converter OEC5e. A wake-up signal WAKEUPe may be transferred from the memory controller 210e to the memory device 230e through the electrical signal line ELe.

The power controller PCUe may generate a power control signal PCSe based on the command signal and the control signal CC2e of the memory device 230e. The power control signal PCSe may include a first power control signal, a second power control signal, a third power control signal, a fourth power control signal, and a fifth power control signal. A power consumption of the first optical-to-electrical converter OEC1e may be controlled by changing a power delivering level of the first optical-to-electrical converter OEC1e based on the first power control signal. A power consumption of the first electrical-to-optical converter EOC1e may be controlled by changing a power delivering level of the first electrical-to-optical converter EOC1e based on the second power control signal. A power consumption of the third optical-to-electrical converter OEC3e may be controlled by changing a power delivering level of the third optical-to-electrical converter OEC3e based on the third power control signal. A power consumption of the third electrical-to-optical converter EOC3e may be controlled by changing a power delivering level of the third electrical-to-optical converter EOC3e based on the fourth power control signal. A power consumption of the fifth optical-to-electrical converter OEC5e may be controlled by changing a power delivering level of the fifth optical-to-electrical converter OEC5e based on the fifth power control signal.

Because the command signal and control signal CC1e of the memory controller 210e cannot be transferred to the memory device 230e when the fifth optical-to-electrical converter OEC5e is disabled by stopping power delivery, the power controller PCUe may generate the power control signal PCSe, which enables the first converter CVT1e or the fifth optical-to-electrical converter OEC5e to deliver power thereto, based on the wake-up signal WAKEUPe.

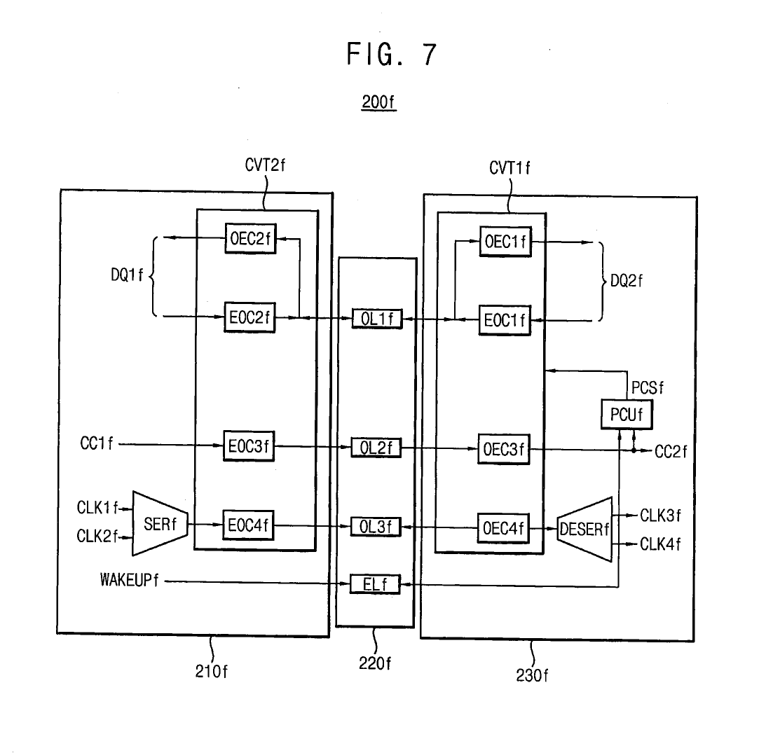

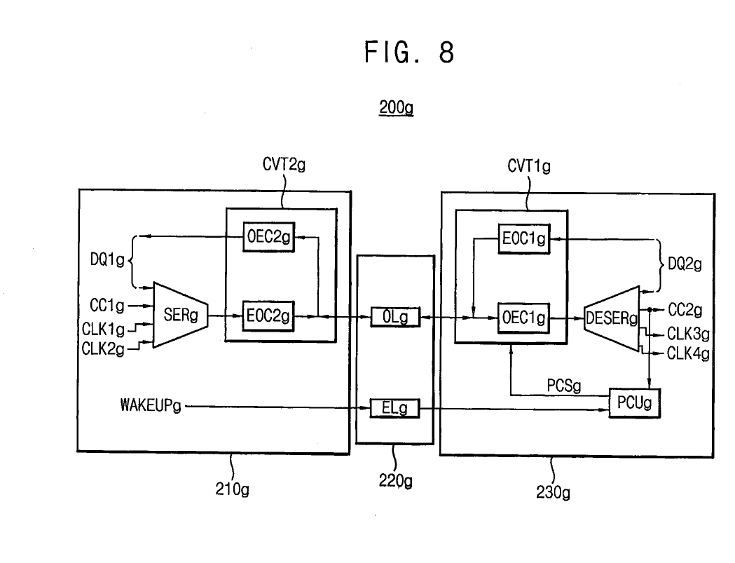

Referring to FIG. 7, a memory system 200f includes a memory controller 210f, a memory device 230f, and a channel 220f. The memory controller 210f and the memory device 230f are connected through the channel 220f including a first optical signal line OL1f, a second optical signal line OL2f, a third optical signal line OL3f, and an electrical signal line EU. The memory device 230f may include a first converter CVT1f, a de-serializer DESERf, and a power controller PCUf. The memory controller 210f may include a second converter CVT2f and a serializer SERf. The first converter CVT1f may include a first optical-to-electrical converter OEC1f, a first electrical-to-optical converter EOC1f, a third optical-to-electrical converter OEC3f, and a fourth optical-to-electrical converter OEC4f. The second converter CVT2f may include a second optical-to-electrical converter OEC2f, a second electrical-to-optical converter EOC2f, a third electrical-to-optical converter EOC3f, and a fourth electrical-to-optical converter EOC4f.

A first data signal DQ1f may be transferred from the memory controller 210f to the memory device 230f through the second electrical-to-optical converter EOC2f, the first optical signal line OL1f, and the first optical-to-electrical converter OEC1f. A second data signal DQ2f may be transferred from the memory device 230f to the memory controller 210f through the first electrical-to-optical converter EOC1f, the first optical signal line OL1f, and the second optical-to-electrical converter OEC2f.

A command signal and a control signal CC1f of the memory controller 210f may be transferred to the memory device 230f as a command signal and a control signal CC2f through the third electrical-to-optical converter EOC3f, the second optical signal line OL2f, and the third optical-to-electrical converter OEC3f. A first clock signal CLK1f and a second clock signal CLK2f of the memory controller 210f may be transferred to the memory device 230f as a transferred first clock signal CLK3f and a transferred second clock signal CLK4f through the serializer SERf, the fourth electrical-to-optical converter EOC4f, the third optical signal line OL3f, the fourth optical-to-electrical converter OEC4f, and the de-serializer DESERf. A wake-up signal WAKEUPf may be transferred from the memory controller 210f to the memory device 230f through the electrical signal line ELf.

The power controller PCUf may generate a power control signal PCSf based on the command signal and the control signal CC2f of the memory device 230f. The power control signal PCSf may include a first power control signal, a second power control signal, a third power control signal, and a fourth power control signal. A power consumption of the first optical-to-electrical converter OEC1f may be controlled by changing a power delivering level of the first optical-to-electrical converter OEC1f based on the first power control signal. A power consumption of the first electrical-to-optical converter EOC1f may be controlled by changing a power delivering level of the first electrical-to-optical converter EOC1f based on the second power control signal. A power consumption of the third optical-to-electrical converter OEC3f may be controlled by changing a power delivering level of the third optical-to-electrical converter OEC3f based on the third power control signal. A power consumption of the fourth optical-to-electrical converter OEC4f may be controlled by changing a power delivering level of the fourth optical-to-electrical converter OEC4f based on the fourth power control signal.

Because the command signal and control signal CC1f of the memory controller 210f cannot be transferred to the memory device 230f when the fourth optical-to-electrical converter OEC4f is disabled by stopping power delivery, the power controller PCUf may generate the power control signal PCSf, which enables the first converter CVT1f or the fourth optical-to-electrical converter OEC4f to deliver power thereto, based on the wake-up signal WAKEUPf.

Referring to FIG. 8, a memory system 200g includes a memory controller 210g, a memory device 230g, and a channel 220g. The memory controller 210g and the memory device 230g are connected through the channel 220g including an optical signal line OLg, and an electrical signal line ELg. The memory device 230g may include a first converter CVT1g, a de-serializer DESERg, and a power controller PCUg. The memory controller 210g may include a second converter CVT2g and a serializer SERg. The first converter CVT1g may include a first optical-to-electrical converter OEC1g and a first electrical-to-optical converter EOC1g. The second converter CVT2g may include a second optical-to-electrical converter OEC2g and a second electrical-to-optical converter EOC2g.

A first data signal DQ1g, a command signal and a control signal CC1g, a first clock signal CLK1g, and a second clock signal CLK2g may be transferred from the memory controller 210g to the memory device 230g as a second data signal DQ2g, a command signal and a control signal CC2g, a transferred first clock signal CLK3g, and a transferred second clock signal CLK4g though the serializer SERg, the second electrical-to-optical converter EOC2g, the optical signal line OLg, the first optical-to-electrical converter OEC1g, and the deserializer DESERg. The second data signal DQ2g may be transferred from the memory device 230g to memory controller 210g as the first data signal DQ1g through the first electrical-to-optical converter EOC1g, the optical signal line OLg, and the second optical-to-electrical converter OEC2g. A wake-up signal WAKEUPg may be transferred from the memory controller 210g to the memory device 230g through the electrical signal line ELg.

The power controller PCUg may generate a power control signal PCSg based on the command signal and the control signal CC2g of the memory device 230g. The power control signal PCSg may include a first power control signal and a second power control signal. A power consumption of the first optical-to-electrical converter OEC1g may be controlled by changing a power delivering level of the first optical-to-electrical converter OEC1g based on the first power control signal. A power consumption of the first electrical-to-optical converter EOC1g may be controlled by changing a power delivering level of the first electrical-to-optical converter EOC1g based on the second power control signal.

Because the command signal and control signal CC1g of the memory controller 210g cannot be transferred to the memory device 230g when the first optical-to-electrical converter OEC1g is disabled by stopping power delivery, the power controller PCUg may generate the power control signal PCSg, which enables the first converter CVT1g or the first optical-to-electrical converter OEC1g to deliver power thereto, based on the wake-up signal WAKEUPg.

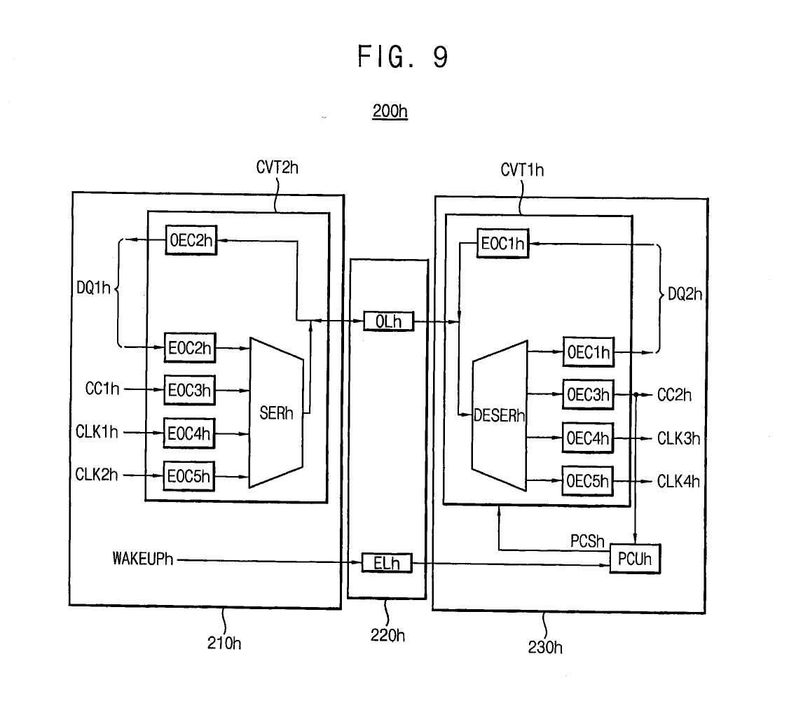

Referring to FIG. 9, a memory system 200h includes a memory controller 210h, a memory device 230h, and a channel 220h. The memory controller 210h and the memory device 230h are connected through the channel 220h including an optical signal line OLh, and an electrical signal line ELh. The memory device 230h may include a first converter CVT1h and a power controller PCUh. The memory controller 210h may include a second converter CVT2h. The first converter CVT1h may include a first electrical-to-optical converter EOC1h, a first optical-to-electrical converter OEC1h, a third optical-to-electrical converter OEC3h, a fourth optical-to-electrical converter OEC4h, a fifth optical-to-electrical converter OEC5h, and an optical de-serializer DESERh. The second converter CVT2h may include a second optical-to-electrical converter OEC2h, a second electrical-to-optical converter EOC2h, a third electrical-to-optical converter EOC3h, a fourth optical-to-electrical converter EOC4h, a fifth electrical-to-optical converter EOC5h, and an optical serializer SERh.

A first data signal DQ1h of the memory controller 210h may be transferred from the memory controller 210h to the memory device 230h as a second data signal DQ2h though the second electrical-to-optical converter EOC2h, the optical serializer SERh, the optical signal line OLh, the optical de-serializer DESERh, and the first optical-to-electrical converter OEC1h. The second data signal DQ2h of the memory device 230h may be transferred from the memory device 230h to the memory controller 210h as the first data signal DQ1h through the first electrical-to-optical converter EOC1h, the optical signal line OLh, and the second optical-to-electrical converter OEC2h.

A command signal and a control signal CC1h may be transferred from the memory controller 210h to the memory device 230h as a command signal and a control signal CC2h of the memory device 230h through the third electrical-to-optical converter EOC3h, the optical serializer SERh, the optical signal line OLh, the optical de-serializer DESERh, and the third optical-to-electrical converter OEC3h.

A first clock signal CLK1h of the memory controller 210h may be transferred from the memory controller 210h to the memory device 230h as a transferred first clock signal CLK3h through the fourth electrical-to-optical converter EOC4h, the optical serializer SERh, the optical signal line OLh, the optical de-serializer DESERh, and the fourth optical-to-electrical converter OEC4h. A second clock signal CLK2h of the memory controller 210h may be transferred from the memory controller 210h to the memory device 230h as a transferred second clock signal CLK4h through the fifth electrical-to-optical converter EOC5h, the optical serializer SERh, the optical signal line OLh, the optical de-serializer DESERh, and the fifth optical-to-electrical converter OEC5h. A wake-up signal WAKEUPh may be transferred from the memory controller 210h to the memory device 230h through the electrical signal line ELh.

The power controller PCUh may generate a power control signal PCSh based on the command signal and the control signal CC2h of the memory device 230h. The power control signal PCSh may include a first power control signal, a second power control signal, a third power control signal, a fourth power control signal, a fifth power control signal, and a sixth power control signal. A power consumption of the first electrical-to-optical converter EOC1h may be controlled by changing a power delivering level of the first electrical-to-optical converter EOC1h based on the first power control signal. A power consumption of the first optical-to-electrical converter OEC1h may be controlled by changing a power delivering level of the first optical-to-electrical converter OEC1h based on the second power control signal. A power consumption of the third optical-to-electrical converter OEC3h may be controlled by changing a power delivering level of the third optical-to-electrical converter OEC3h based on the third power control signal. A power consumption of the fourth optical-to-electrical converter OEC4h may be controlled by changing a power delivering level of the fourth optical-to-electrical converter OEC4h based on the fourth power control signal. A power consumption of the fifth optical-to-electrical converter OEC5h may be controlled by changing a power delivering level of the fifth optical-to-electrical converter OEC5h based on the fifth power control signal. A power consumption of the optical de-serializer DESERh may be controlled by changing a power delivering level of the optical de-serializer DESERh based on the sixth power control signal.

Because the command signal and control signal CC1h of the memory controller 210h cannot be transferred to the memory device 230h when the third optical-to-electrical converter OEC3h and the optical de-serializer DESERh are disabled by stopping power delivery, the power controller PCUh may generate the power control signal PCSh, which enables the first converter CVT1h, or enables the third optical-to-electrical converter OEC3h and the optical de-serializer DESERh to deliver power thereto, based on the wake-up signal WAKEUPh.

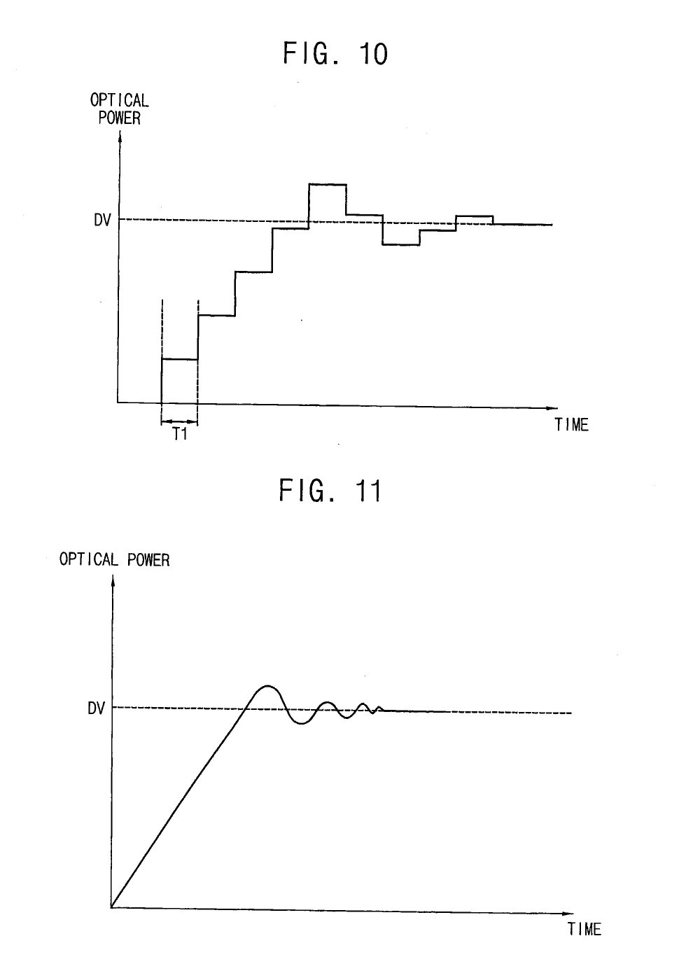

FIGS. 10 and 11 are graphs illustrating example embodiments of controlling power consumption of converters included in the memory system of FIG. 3.

FIG. 10 is a graph illustrating an example embodiment in which power consumption OPTICAL POWER of the converters CVT1b, CVT2b included in the memory system 200b of FIG. 3 is controlled periodically. The period of controlling the power consumption OPTICAL POWER is T1.

In an example embodiment, when the first power controller PCU1b receives the transferred first test signal TTS1 having a lower intensity than a lower boundary intensity, the first power controller PCU1b may generate the first power control signal PCS1b that makes the first optical-to-electrical converter OEC1b more sensitive to an optical signal. When the first power controller PCU1b receives the transferred first test signal TTS1 having a lower intensity than the lower boundary intensity, the first power controller PCU1b may control the first flag signal FS1 so that the second power controller PCU2b generates the fourth power control signal PCS4b, which enhances the output intensity of the second electrical-to-optical converter EOC2b. In this case, the power consumption OPTICAL POWER, which is less than a desired power consumption DV, may be increased.

When the first power controller PCU1b receives the transferred first test signal TTS1 having a higher intensity than a upper boundary intensity, the first power controller PCU1b may generate the first power control signal PCS1b that makes the first optical-to-electrical converter OEC1b less sensitive to an optical signal. When the first power controller PCU1b receives the transferred first test signal TTS1 having a higher intensity than the upper boundary intensity, the first power controller PCU1b may control the first flag signal FS 1 so that the second power controller PCU2b generates the fourth power control signal PCS4b, which reduces the output intensity of the second electrical-to-optical converter EOC2b. In this case, the power consumption OPTICAL POWER, which is greater than the desired power consumption DV, may be decreased.

FIG. 11 is a graph illustrating an example embodiment in which power consumption OPTICAL POWER of the converters CVT1b, CVT2b included in the memory system 200b of FIG. 3 is controlled continuously. FIG. 11 may be understood based on the reference to FIG. 10.

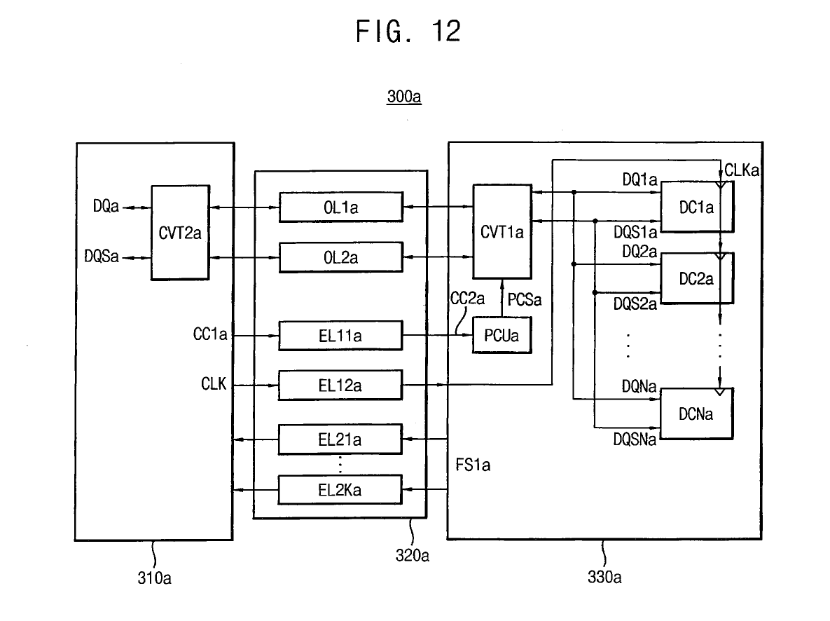

FIG. 12 is a block diagram illustrating a memory system according to an example embodiment.

Referring to FIG. 12, a memory system 300a includes a memory controller 310a, a memory device 330a, and a channel 320a. The memory controller 310a and the memory device 330a are connected through the channel 320a including a first optical signal line OL1a, a second optical signal line OL2a, first electrical signal lines EU1a, EL12a, and second electrical signal lines EL21a, EL2Ka. The memory device 330a may include a first converter CVT1a, a power controller PCUa, and a plurality of DRAM chips DC1a, DC2a, and DCNa. The memory controller 310a may include a second converter CVT2a.

The second converter CVT2a may convert a data signal DQa and a data strobe signal DQSa to an optical signal. The memory controller 310a may transfer the optical signal to the memory device 330a through the first optical signal line OL1a and the second optical signal line OL2a. The memory controller 310a may transfer a command signal and a control signal CC1a to the memory device 330a through the first electrical signal lines EL11a, EL12a. The memory controller 310a may transfer a clock signal CLK to the memory device 330a through the first electrical signal lines EL11a, EL12a.

The first converter CVT1a may generate a converted first data signal DQ1a, a converted second data signal DQ2a, and a converted (N)th data signal DQNa based on an optical signal transferred through the first optical signal line OL1a. The converted first data signal DQ1a, the converted second data signal DQ2a, and the converted (N)th data signal DQNa have the same information as the data signal DQa. The converted first data signal DQ1a, the converted second data signal DQ2a, and the converted (N)th data signal DQNa may have different timings relative to each other.

The first converter CVT1a may generate a converted first data strobe signal DQS1a, a converted second data strobe signal DQS2a, and a converted (N)th data strobe signal DQSNa based on an optical signal transferred through the second optical signal line OL2a. The converted first data strobe signal DQS1a, the converted second data strobe signal DQS2a, and the converted (N)th data strobe signal DQSNa have the same information as the data strobe signal DQSa. The converted first data strobe signal DQS1a, the converted second data strobe signal DQS2a, and the converted (N)th data strobe signal DQSNa may have different timings relative to each other.

The first converter CVT1a may transfer the converted first data signal DQ1a and the converted first data strobe signal DQS1a to a first DRAM chip DC1a when data is written to the first DRAM chip DC1a. The first converter CVT1a may receive the converted first data signal DQ1a and the converted first data strobe signal DQS1a from the first DRAM chip DC1a when data is read from the first DRAM chip DC1a. The first converter CVT1a may transfer the converted second data signal DQ2a and the converted second data strobe signal DQS2a to a second DRAM chip DC2a when data is written to the second DRAM chip DC2a. The first converter CVT1a may receive the converted second data signal DQ2a and the converted second data strobe signal DQS2a from the second DRAM chip DC2a when data is read from the second DRAM chip DC2a. The first converter CVT1a may transfer the converted (N)th data signal DQNa and the converted (N)th data strobe signal DQSNa to a (N)th DRAM chip DCNa when data is written to the (N)th DRAM chip DCNa. The first converter CVT1a may receive the converted (N)th data signal DQNa and the converted (N)th data strobe signal DQSNa from the (N)th DRAM chip DC1a when data is read from the (N)th DRAM chip DCNa.

Power consumption of the first converter CVT1a may be controlled based on a power control signal PCSa, which is generated by the power controller PCUa based on a transferred command signal and a transferred control signal.

A clock signal CLK of the memory controller 310a may be transferred to a clock signal CLKa of the memory device 330a. The clock signal CLKa may be input to each of the DRAM chips DC1a, DC2a, and DCNa. The clock signal CLKa may have delayed timing compared to the clock signal CLK. When the command signal is a write-leveling command signal, the memory device 330a may generate a feedback signal FS1a representing a phase difference between the clock signal CLKa and the converted data strobe signals DQS1a, DQS2a, and DQSNa, and may transfer the feedback signal FS1a to the memory controller 310a through the second electrical signal lines EL21a, EL2Ka.

The memory controller 310a may reconfigure a delay time of the data strobe signal DQSa based on the feedback signal FS1a transferred through the second electrical signal lines EL21a, EL2Ka.

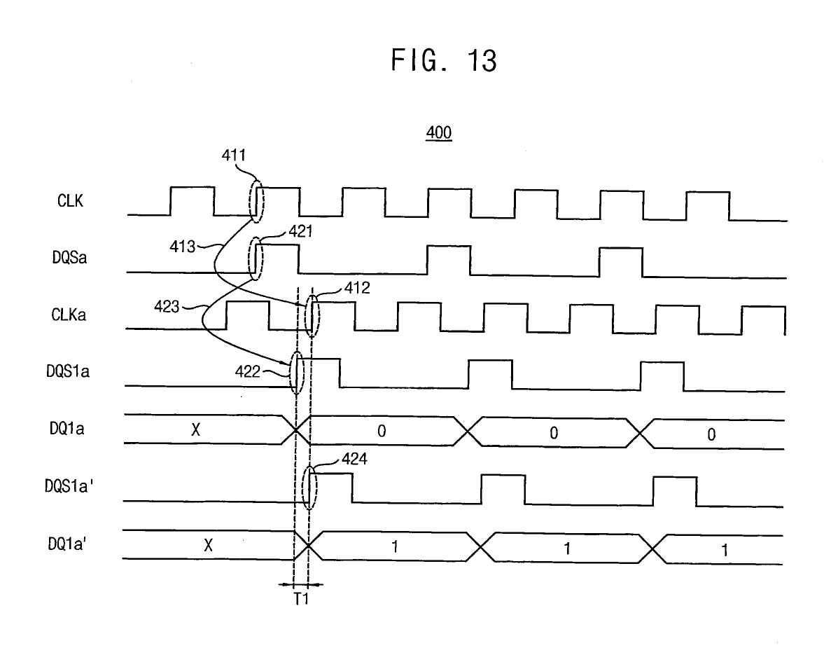

FIG. 13 is a timing diagram illustrating a write-leveling operation of the memory system of FIG. 12. FIG. 13 illustrates timing of the converted first data signal DQ1a and the converted first data strobe signal DQS1a of the memory system 300a of FIG. 12. Other converted data signals DQ2a, DQNa and other converted data strobe signals DQS2a, DQSNa may be understood based on the reference to FIG. 13.

Referring to FIG. 13, in general, a write-leveling indicates a procedure outputting a latched value of the clock signal CLKa at a rising edge of the converted first data strobe signal DQS1a to check synchronization between the clock signal CLKa and the converted first data strobe signal DQS1a of the memory system 300a of FIG. 12.

A rising edge 411 of the clock signal CLK of the memory controller 310a and a rising edge 421 of the data strobe signal DQSa of the memory controller 310a are aligned together. In general, a rising edge 412 of the clock signal CLKa of the memory device 330a and a rising edge 422 of the converted first data strobe signal DQS1a of the memory device 330a may not be aligned because of delay in the channel 320a. If the write-leveling is performed when the rising edge 412 of the clock signal CLKa and the rising edge 422 of the converted first data strobe signal DQS1a are not aligned, the memory device 330a outputs a value of 0, which is a latched value of the converted first data strobe signal DQS1a at the rising edge 412 of the clock signal CLKa, as the converted first data signal DQ1a and the first DRAM chip DC1a may not operate as desired.

To better operate the first DRAM chip DC1a, the memory device 330a may transfer the converted first data signal DQ1a, which has a value of 0, as the feedback signal FS1a to the memory controller 310a. The memory controller 310a may increase a delay time of the data strobe signal DQSa until the feedback signal FS1a has a value of 1. When the rising edge 412 of the clock signal CLKa and a rising edge 424 of the converted first data strobe signal, which the delay time is applied to DQS1a′ are aligned together, the memory device 330a outputs a value of 1 as the converted first data signal, which the delay time is applied to DQ1a′ and the first DRAM chip DC1a may operate as desired.

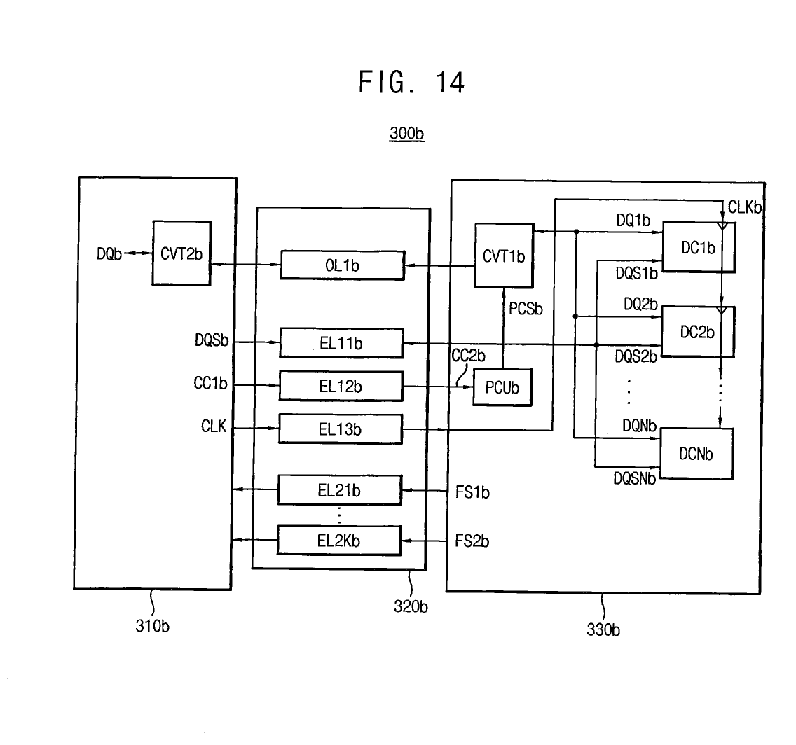

FIG. 14 is a block diagram illustrating a memory system according to an example embodiment.

Referring to FIG. 14, a memory system 300b includes a memory controller 310b, a memory device 330b, and a channel 320b. The memory controller 310b and the memory device 330b are connected through the channel 320b including a first optical signal line OL1b, first electrical signal lines EL11b, EL12b, and EL13b, and second electrical signal lines EL21b, EL2Kb. The memory device 330b may include a first converter CVT1b, a power controller PCUb, and a plurality of DRAM chips DC1b, DC2b, and DCNb. The memory controller 310b may include a second converter CVT2b.

The second converter CVT2b may convert a data signal DQb of the memory controller 310b to the optical signal. The memory controller 310b may transfer the optical signal to the memory device 330b through the first optical signal line OL1b. The memory controller 310b may transfer a data strobe signal DQSb, a command signal and a control signal CC1b, and a clock signal CLK to the memory device 330b through first electrical signal lines EL11b, EL12b, and EL13b included in the channel 320b.

The first converter CVT1b converts the optical signal to converted data signals DQ1b, DQ2b, and DQNb. The memory device 330b outputs a first feedback signal FS1b, which represents a phase difference between the clock signal CLKa and the data strobe signals DQS1b, DQS2b, and DQSNb input to the DRAM chips DC1b, DC2b, and DCNb, and a second feedback signal FS2b, which represents a phase difference between the data strobe signals DQS1b, DQS2b, and DQSNb and the converted data signal DQ1b, DQ2b, and DQNb input to the DRAM chips DC1b, DC2b, and DCNb, when the command signal is the write-leveling command signal.

The memory controller 310b may reconfigure a delay time of the data strobe signal DQSb and a delay time of the data signal DQb based on the first feedback signal FS1b and the second feedback signal FS2b received through the second electrical signal lines EL21b, EL2Kb when the command signal is a write-leveling command signal.

A process aligning rising edges of the clock signal CLKb, the data strobe signals DQS1b, DQS2b, and DQSNb and the converted data signals DQ1b, DQ2b, and DQNb may be understood based on the reference to FIG. 13.

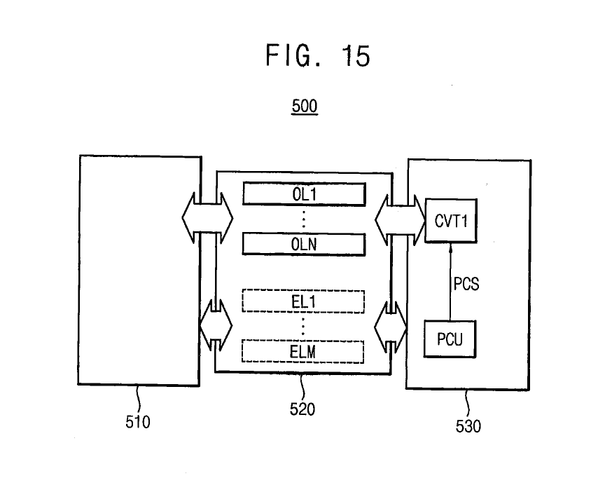

FIG. 15 is a block diagram illustrating a computing system according to an example embodiment.

Referring to FIG. 15, a computing system 500 includes a master circuit 510, a slave circuit 530, and a channel 520. The master circuit 510 and the slave circuit 530 are connected through the channel 520 including at least one optical signal line OL1, OLN. The slave circuit 530 includes a converter CVT1 and a power controller PCU. The converter CVT converts between at least one optical signal of the optical signal line OL1, OLN and at least one internal electrical signal of the slave circuit 530. The power controller PCU controls a power consumption of the converter CVT based on an operating state of the slave circuit 530.

The computing system 500 may be understood based on the references to FIGS. 1 through 11.

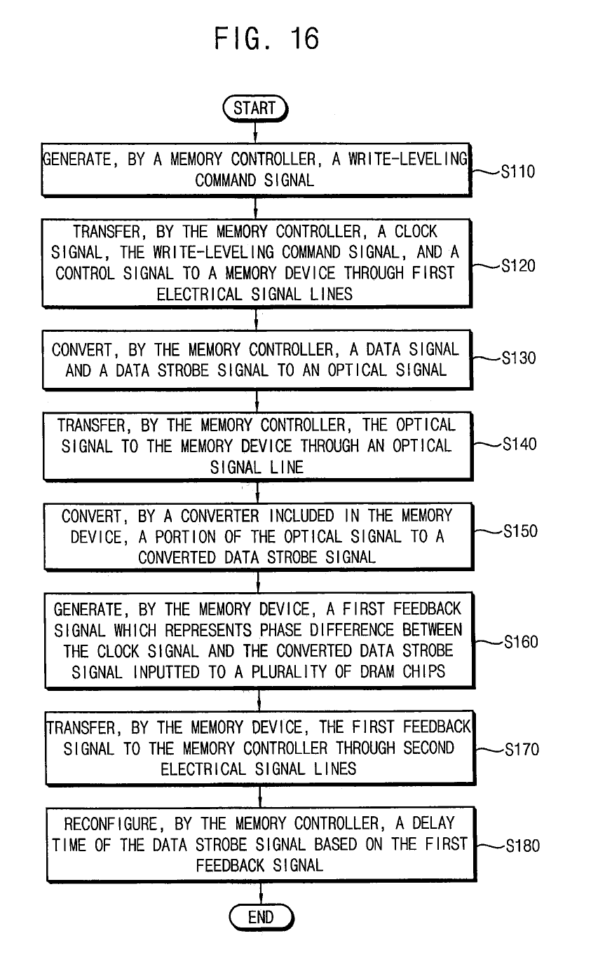

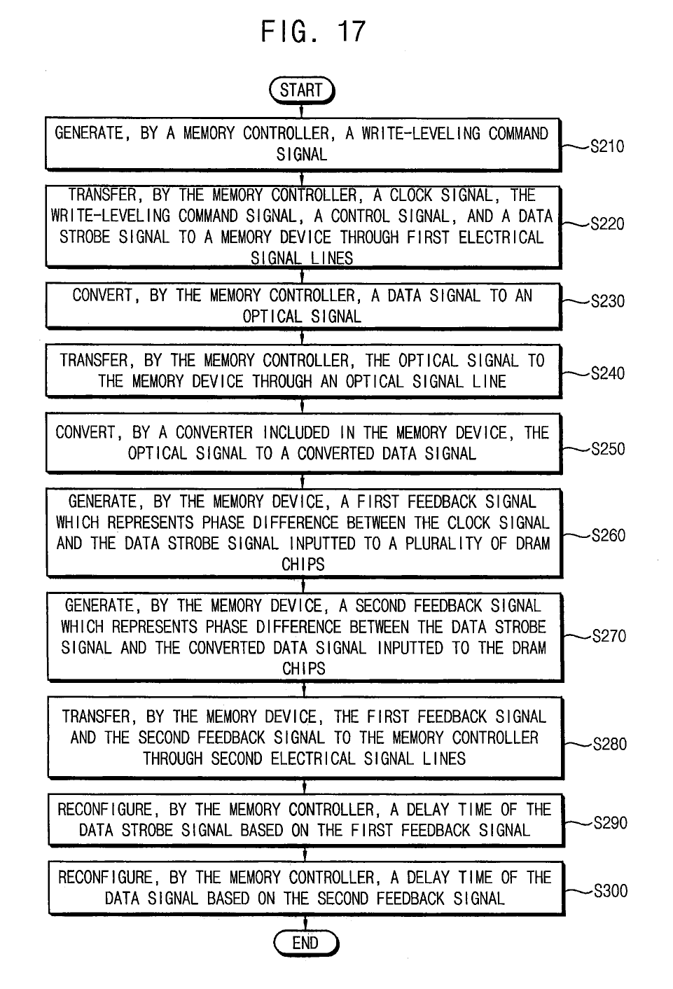

FIGS. 16 and 17 are flow charts illustrating example embodiments of write-leveling method of a memory system according to example embodiments.

Referring to FIG. 16, to perform write-leveling, a memory controller generates a write-leveling command signal (S110). The memory controller transfers a clock signal, the write-leveling command signal, and a control signal to a memory device (S120) through first electrical signal lines. The memory controller converts a data signal and a data strobe signal to an optical signal (S130). The memory controller transfers the optical signal to the memory device (S140) through an optical signal line.

A converter included in the memory device may convert a portion of the optical signal to a converted data strobe signal (S150). The memory device may generate a first feedback signal (S160), which represents a phase difference between the clock signal and the converted data strobe signal input to a plurality of DRAM chips. The memory device may transfer the first feedback signal to the memory controller through second electrical signal lines (S170).

The memory controller may reconfigure a delay time of the data strobe signal based on the first feedback signal (S180).

The generating, by a memory controller, a write-leveling command signal (S110), the transferring, by the memory controller, a clock signal, the write-leveling command signal, and a control signal to a memory device (S120), the converting, by the memory controller, a data signal and a data strobe signal to an optical signal (S130), the transferring, by the memory controller, the optical signal to the memory device (S140), the converting, by a converter included in the memory device, a portion of the optical signal to a converted data strobe signal (S150), the generating, by the memory device, a first feedback signal which represents a phase difference between the clock signal and the converted data strobe signal input to a plurality of DRAM chips (S160), the transferring, by the memory device, the first feedback signal to the memory controller through second electrical signal lines (S170), and the reconfiguring, by the memory controller, a delay time of the data strobe signal based on the first feedback signal (S180) may be understood based on the references to FIGS. 12 and 13.

Referring to FIG. 17, to perform write-leveling, a memory controller generates a write-leveling command signal (S210). The memory controller transfers a clock signal, the write-leveling command signal, a control signal, and a data strobe signal to a memory device (S220) through first electrical signal lines. The memory controller converts a data signal to an optical signal (S230). The memory controller transfers the optical signal to the memory device (S240) through an optical signal line.

A converter included in the memory device may convert the optical signal to a converted data signal (S250). The memory device may generate a first feedback signal (S260), which represents a phase difference between the clock signal and the data strobe signal input to a plurality of DRAM chips. The memory device may generate a second feedback signal (S270), which represents a phase difference between the data strobe signal and the converted data signal input to the DRAM chips. The memory device may transfer the first feedback signal and the second feedback signal to the memory controller through second electrical signal lines (S280).

The memory controller may reconfigure a delay time of the data strobe signal based on the first feedback signal (S290). The memory controller may reconfigure a delay time of the data signal based on the second feedback signal (S300).

The generating, by a memory controller, a write-leveling command signal (S210), the transferring, by the memory controller, a clock signal, the write-leveling command signal, a control signal, and a data strobe signal to a memory device (S220), the converting, by the memory controller, a data signal to an optical signal (S230), the transferring, by the memory controller, the optical signal to the memory device (S240), the converting, by a converter included in the memory device, the optical signal to a converted data signal (S250), the generating, by the memory device, a first feedback signal which represents a phase difference between the clock signal and the data strobe signal input to a plurality of DRAM chips (S260), the generating, by the memory device, a second feedback signal which represents a phase difference between the data strobe signal and the converted data signal input to the DRAM chips (S270), the transferring, by the memory device, the first feedback signal and the second feedback signal to the memory controller through second electrical signal lines (S280), the reconfiguring, by the memory controller, a delay time of the data strobe signal based on the first feedback signal (S290), and the reconfiguring, by the memory controller, a delay time of the data signal based on the second feedback signal (S300) may be understood based on the references to FIG. 14.

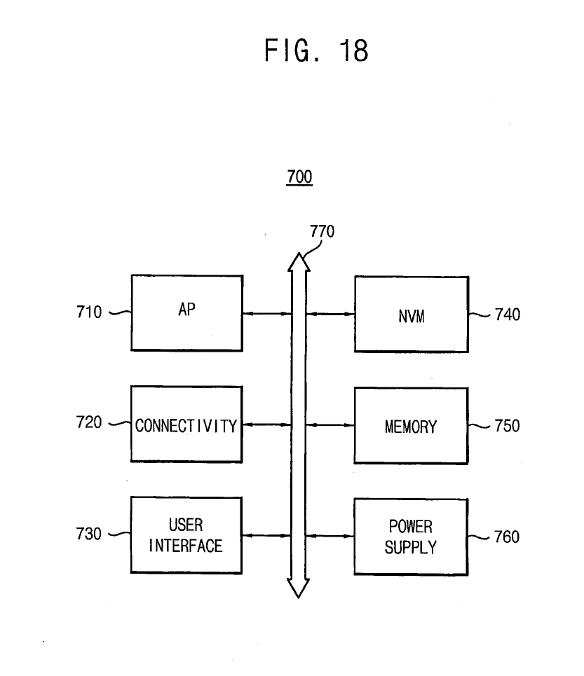

FIG. 18 is a block diagram illustrating a mobile system including a memory system according to example embodiments.

Referring to FIG. 18, a mobile system 700 includes an application processor (AP) 710, a connectivity unit 720, a memory device 750, a nonvolatile memory (NVM) device 740, a user interface 730, a bus 770 and a power supply 760. In an exemplary embodiment the mobile system 700 may be a mobile phone, a smart phone, a personal digital assistant (PDA), a portable multimedia player (PMP), a digital camera, a music player, a portable game console, a navigation system, etc.

The application processor 710 may execute applications, such as a web browser, a game application, a video player, etc. In an exemplary embodiment the application processor 710 may include a single core or multiple cores. For example, the application processor 710 may be a multi-core processor, such as a dual-core processor, a quad-core processor, a hexa-core processor, and the like. The application processor 710 may include an internal or external cache memory.

The connectivity unit 720 may perform wired or wireless communication with an external device. For example, the connectivity unit 720 may perform Ethernet communication, near field communication (NFC), radio frequency identification (RFID) communication, mobile telecommunication, memory card communication, universal serial bus (USB) communication, etc. In an exemplary embodiment, the connectivity unit 720 may include a baseband chipset that supports communications, such as global system for mobile communications (GSM), general packet radio service (GPRS), wideband code division multiple access (WCDMA), high speed downlink/uplink packet access (HSxPA), etc.

The memory device 750 may store data processed by the application processor 710, or may operate as a working memory. Each of memory cells included in the memory device 750 may include a write transistor, a read transistor and a metal oxide semiconductor (MOS) capacitor. The write transistor may include a gate electrode coupled to a write word line, a first electrode coupled to a write bit line and a second electrode coupled to a storage node. The read transistor may include a gate electrode coupled to the storage node, a first electrode coupled to a read word line and a second electrode coupled to a read bit line. The MOS capacitor may include a gate electrode coupled to the storage node and a lower electrode coupled to a synchronization control line. A synchronization pulse signal may be applied to the lower electrode of the MOS capacitor in synchronization with a write word line signal in a write operation and applied to the lower electrode of the MOS capacitor in synchronization with a read word line signal in a read operation such that a coupling effect may occur at the storage node through the MOS capacitor in response to the synchronization pulse signal. Therefore, a data retention time of the memory cell included in the memory device 750 may increase. As such, the memory device 750 may have a longer data retention time than a dynamic random access memory (DRAM) and a higher density than a static random access memory (SRAM).

The application processor 710 may operate as the memory controller which is included in the memory systems of FIGS. 1 through 9, or included in the memory systems of FIGS. 12 and 14. The memory device 750 may operate as the memory device which is included in the memory systems of FIGS. 1 through 9, or included in the memory systems of FIGS. 12 and 14. The bus 770 may be the channel, which is included in the memory systems of FIGS. 1 through 9, or included in the memory systems of FIGS. 12 and 14. A detailed description of the memory controller, the memory device, and the channel will be omitted.

The nonvolatile memory device 740 may store a boot image for booting the mobile system 700. For example, the nonvolatile memory device 740 may be an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), etc.

The user interface 730 may include at least one input device, such as a keypad, a touch screen, etc., and at least one output device, such as a speaker, a display device, etc. The power supply 760 may supply a power supply voltage to the mobile system 700.

In some embodiments, the mobile system 700 may further include an image processor, and/or a storage device, such as a memory card, a solid state drive (SSD), a hard disk drive (HDD), a CD-ROM, etc.

In some embodiments, the mobile system 700 and/or components of the mobile system 700 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

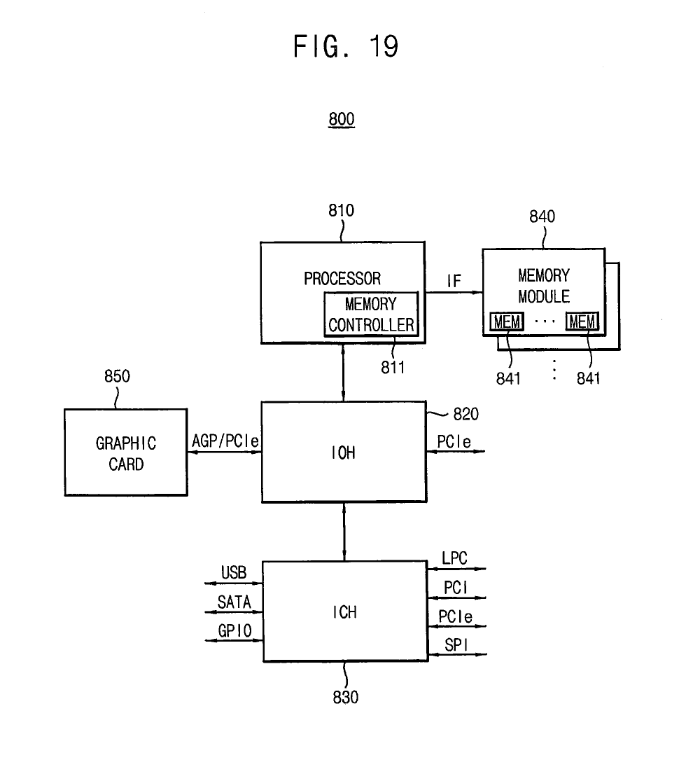

FIG. 19 is a block diagram illustrating a computing system including a memory system according to example embodiments.

Referring to FIG. 19, a computing system 800 includes a processor 810, an input/output hub (IOH) 820, an input/output controller hub (ICH) 830, at least one memory module 840 and a graphics card 850. In some embodiments, the computing system 800 may be a personal computer (PC), a server computer, a workstation, a laptop computer, a mobile phone, a smart phone, a personal digital assistant (PDA), a portable multimedia player (PMP), a digital camera), a digital television, a set-top box, a music player, a portable game console, a navigation system, etc.

The processor 810 may perform various computing functions, such as executing specific software for performing specific calculations or tasks. For example, the processor 810 may be a microprocessor, a central process unit (CPU), a digital signal processor, or the like. In some embodiments, the processor 810 may include a single core or multiple cores. For example, the processor 810 may be a multi-core processor, such as a dual-core processor, a quad-core processor, a hexa-core processor, etc. Although FIG. 19 illustrates the computing system 800 including one processor 810, in some embodiments, the computing system 800 may include a plurality of processors.

The processor 810 may include a memory controller MEMORY CONTROLLER 811 for controlling operations of the memory module 840. The memory controller 811 included in the processor 810 may be referred to as an integrated memory controller (IMC). A memory interface IF between the memory controller 811 and the memory module 840 may be implemented with a single channel including a plurality of signal lines, or may bay be implemented with multiple channels, to each of which at least one memory module 840 may be coupled. In some embodiments, the memory controller 811 may be located inside the input/output hub 820. The input/output hub 820 including the memory controller 811 may be referred to as memory controller hub (MCH).

The memory module 840 may include a plurality of memory devices MEM 841 that store data provided from the memory controller 811. Each of memory cells included in the memory device 841 may include a write transistor, a read transistor and a metal oxide semiconductor (MOS) capacitor. The write transistor may include a gate electrode coupled to a write word line, a first electrode coupled to a write bit line and a second electrode coupled to a storage node. The read transistor may include a gate electrode coupled to the storage node, a first electrode coupled to a read word line and a second electrode coupled to a read bit line. The MOS capacitor may include a gate electrode coupled to the storage node and a lower electrode coupled to a synchronization control line. A synchronization pulse signal may be applied to the lower electrode of the MOS capacitor in synchronization with a write word line signal in a write operation and applied to the lower electrode of the MOS capacitor in synchronization with a read word line signal in a read operation such that a coupling effect may occur at the storage node through the MOS capacitor in response to the synchronization pulse signal. Therefore, a data retention time of the memory cell included in the memory device 841 may increase. As such, the memory device 841 may have a longer data retention time than a dynamic random access memory (DRAM) and a higher density than a static random access memory (SRAM).

The memory controller 811 may operate as the memory controller, which is included in the memory systems of FIGS. 1 through 9, or included in the memory systems of FIGS. 12 and 14. The memory module 840 may operate as the memory device, which is included in the memory systems of FIGS. 1 through 9, or included in the memory systems of FIGS. 12 and 14. The memory interface IF may be the channel which is included in the memory systems of FIGS. 1 through 9, or included in the memory systems of FIGS. 12 and 14. A detailed description of the memory controller, the memory device, and the channel will be omitted.

The input/output hub 820 may manage data transfer between processor 810 and devices, such as the graphics card 850. The input/output hub 820 may be coupled to the processor 810 via various interfaces. For example, the interface between the processor 810 and the input/output hub 820 may be a front side bus (FSB), a system bus, a HyperTransport, a lightning data transport (LDT), a QuickPath interconnect (QPI), a common system interface (CSI), etc. The input/output hub 820 may provide various interfaces with the devices. For example, the input/output hub 820 may provide an accelerated graphics port (AGP) interface, a peripheral component interface-express (PCIe), a communications streaming architecture (CSA) interface, etc. Although FIG. 19 illustrates the computing system 800 including one input/output hub 820, in some embodiments, the computing system 800 may include a plurality of input/output hubs.

The graphics card 850 may be coupled to the input/output hub 820 via AGP or PCIe. The graphics card 850 may control a display device for displaying an image. The graphics card 850 may include an internal processor for processing image data and an internal memory device. In some embodiments, the input/output hub 820 may include an internal graphics device along with or instead of the graphics card 850 outside the graphics card 850. The graphics device included in the input/output hub 820 may be referred to as integrated graphics. Further, the input/output hub 820 including the internal memory controller and the internal graphics device may be referred to as a graphics and memory controller hub (GMCH).

The input/output controller hub 830 may perform data buffering and interface arbitration to efficiently operate various system interfaces. The input/output controller hub 830 may be coupled to the input/output hub 820 via an internal bus, such as a direct media interface (DMI), a hub interface, an enterprise Southbridge interface (ESI), PCIe, etc.

The input/output controller hub 830 may provide various interfaces with peripheral devices. For example, the input/output controller hub 830 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In some embodiments, the processor 810, the input/output hub 820 and the input/output controller hub 830 may be implemented as separate chipsets or separate integrated circuits. In other embodiments, at least two of the processor 810, the input/output hub 820 and the input/output controller hub 830 may be implemented as a single chipset.

Example embodiments can be applied to a system using a memory controller and a memory device. For instance, example embodiments can be applied to various terminals, such as a mobile phone, a smart phone, a personal digital assistant (PDA), a portable multimedia player (PMP), a digital camera, a camcorder, a personal computer, a sever computer, a workstation, a laptop computer, a digital TV, a set-top box, a music player, a portable game console, a navigation system, a smart card, and a printer.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A memory system comprising:
a memory controller; and
a memory device connected to the memory controller through a channel comprising at least one optical signal line, the memory device comprising:
a first converter configured to convert between at least one optical signal of the at least one optical signal line and at least one internal electrical signal of the memory device; and
a first power controller configured to control power consumption of the first converter based on an operating state of the memory device.

2. The memory system of claim 1, wherein the first converter comprises an optical-to-electrical converter and an electrical-to-optical converter,
wherein the first power controller generates a first power control signal controlling a power consumption of the optical-to-electrical converter in the first converter, and a second power control signal controlling power consumption of the electrical-to-optical converter in the first converter.

3. The memory system of claim 2, wherein the first power controller generates the first and the second power control signals based on a command signal and/or a control signal received from the memory controller.

4. The memory system of claim 3, wherein the first power controller generates the first and the second power control signals disabling the optical-to-electrical converter and the electrical-to-optical converter in the first converter when the memory device executes an operation, which does not use the first converter, in response to the command signal and/or the control signal.

5. The memory system of claim 3, wherein the first power controller generates the first power control signal disabling the optical-to-electrical converter in the first converter when the memory device executes an operation, which does not use the optical-to-electrical converter, in response to the command signal and/or the control signal,
wherein the first power controller generates the second power control signal disabling the electrical-to-optical converter in the first converter when the memory device executes an operation, which does not use the electrical-to-optical converter, in response to the command signal and/or the control signal.

6. The memory system of claim 2, wherein a data signal, a data strobe signal, a command signal, a control signal, and a clock signal of the memory controller are transferred to the memory device through the at least one optical signal line and the optical-to-electrical converter.

7. The memory system of claim 2, wherein the channel further comprises an electrical signal line connecting the memory controller and the memory device,
wherein a data signal of the memory controller is transferred to the memory device through the at least one optical signal line and the optical-to-electrical converter,
wherein each of a data strobe signal, a command signal, a control signal, and a clock signal of the memory controller is transferred to the memory device through the at least one optical signal line and the optical-to-electrical converter, or through the electrical signal line.

8. The memory system of claim 2, wherein the memory controller further comprises a second converter configured to convert between at least one internal electrical signal of the memory controller and the at least one optical signal.

9. The memory system of claim 8, wherein the memory controller further comprises a second power controller,
wherein the second converter includes an optical-to-electrical converter and an electrical-to-optical converter,
wherein the second power controller generates a third power control signal controlling power consumption of the optical-to-electrical converter in the second converter, and a fourth power control signal controlling power consumption of the electrical-to-optical converter in the second converter.

10. The memory system of claim 9, wherein the first power controller generates the first power control signal controlling a sensitivity of the optical-to-electrical converter in the first converter based on a test signal transferred from the memory controller to the memory device, or the second power controller generates the fourth power control signal controlling an output intensity of the electrical-to-optical converter in the second converter based on a first flag signal generated by the first power controller based on the test signal.

11. The memory system of claim 9, wherein the second power controller generates the third power control signal controlling a sensitivity of the optical-to-electrical converter in the second converter based on a test signal transferred from the memory device to the memory controller, or the first power controller generates the second power control signal controlling an output intensity of the electrical-to-optical converter in the first converter based on a second flag signal generated by the second power controller based on the test signal.

12. The memory system of claim 2, wherein the first power controller generates the first and the second power control signals based on a temperature of the first converter and/or a temperature of the memory device.

13. The memory system of claim 2, wherein the at least one optical signal line comprises a both-way optical signal line,
wherein a wavelength of a first optical signal transferred from the both-way optical signal line to the optical-to-electrical converter in the first converter and a wavelength of a second optical signal transferred from the electrical-to-optical converter in the first converter to the both-way optical signal line are different.

14. The memory system of claim 2, wherein the at least one optical signal line comprises a one-way optical signal line,
wherein optical signals, which have different wavelengths, are transferred through the one-way optical signal line simultaneously.

15. The memory system of claim 8, wherein the second converter converts a data signal and a data strobe signal of the memory controller to the at least one optical signal, the memory controller transfers the at least one optical signal to the memory device through the at least one optical signal line, the memory controller transfers a control signal, a command signal, and a clock signal to the memory device through first electrical signal lines in the channel, and the memory controller reconfigures a delay time of the data strobe signal based on a feedback signal received through second electrical signal lines in the channel when the command signal is a write-leveling command signal,
wherein the first converter converts a portion of the at least one optical signal to a converted data strobe signal of the memory device, and the memory device outputs the feedback signal, which represents a phase difference between the clock signal and the converted data strobe signal input to a plurality of DRAM chips, through the second electrical signal lines when the command signal is the write-leveling command signal.

16. The memory system of claim 8, wherein the second converter converts a data signal of the memory controller to the at least one optical signal, the memory controller transfers the at least one optical signal to the memory device through the at least one optical signal line, the memory controller transfers a data strobe signal, a control signal, a command signal, and a clock signal to the memory device through first electrical signal lines in the channel, and the memory controller reconfigures a delay time of the data strobe signal and a delay time of the data signal based on a first feedback signal and a second feedback signal received through second electrical signal lines in the channel when the command signal is a write-leveling command signal,
wherein, the first converter converts the at least one optical signal to a converted data signal of the memory device, and the memory device outputs the first feedback signal, which represents a phase difference between the clock signal and the data strobe signal input to a plurality of DRAM chips, and the second feedback signal, which represents a phase difference between the data strobe signal and the converted data signal input to the DRAM chips, when the command signal is the write-leveling command signal.

17. A computing system comprising:
a master circuit; and
a slave circuit connected to the master circuit through a channel including at least one optical signal line, the slave circuit comprising:
a converter configured to convert between at least one optical signal of the at least one optical signal line and at least one internal electrical signal of the slave circuit; and
a power controller configured to control a power consumption of the converter based on an operating state of the slave circuit.

18. A memory device, comprising:
a converter circuit that is configured to generate an electrical signal responsive to an optical signal; and
a power controller coupled to the converter circuit that is configured to switch the converter circuit between an active state and a disabled state based on an operating state of the memory device.

19. The memory device of claim 18, wherein the power controller is configured to switch the converter circuit to a disabled state when the memory device executes an operation in which the converter circuit is not used.

20. The memory device of claim 18, wherein the power controller is configured to switch the converter circuit between the active state and the disabled state based on a temperature of the converter circuit and/or a temperature of the memory device.
